(19) United States
(12) Patent Application Publication
(10) Pub. No.: US 2020/0152551 A1
(43) Pub. Date: May 14, 2020

(54) STACKED SEMICONDUCTOR DEVICES AND METHODS OF MANUFACTURING THE SAME

(71) Applicant: HUAIAN IMAGING DEVICE MANUFACTURER CORPORATION, HUAIAN (CN)

(72) Inventors: Bin GUAN, HUAIAN (CN); Kishou KANEKO, HUAIAN (CN); Shijie CHEN, HUAIAN (CN); Xiaolu HUANG, HUAIAN (CN)

(73) Assignee: HUAIAN IMAGING DEVICE MANUFACTURER CORPORATION, HUAIAN (CN)

(21) Appl. No.: 16/679,965

(22) Filed: Nov. 11, 2019

(30) Foreign Application Priority Data
Nov. 13, 2018 (CN) 201811343698.1

(51) Int. Cl. H01L 23/48; H01L 21/768; H01L 23/538; H01L 23/522

(52) U.S. Cl. CPC H01L 23/481; H01L 23/5226; H01L 23/5383; H01L 21/76898

(57) ABSTRACT

A stacked semiconductor device including a first substrate, a first insulating layer located on the first substrate, a second insulating layer located on the first insulating layer, a second substrate located on the second insulating layer, an external connection via extending through the second substrate in a first direction perpendicular to an upper surface of the second substrate and exposing an external connection pad, the external connection pad being located in the first insulating layer or the second insulating layer, and a protective ring formed in the second insulating layer and arranged to at least partially surround a sidewall of the external connection via with the first direction as an axial direction, but not to be exposed from the sidewall of the external connection via.

### CROSS-REFERENCE TO RELATED APPLICATIONS

This application claims priority to Chinese Patent Application No. 201811343698.1 filed on Nov. 13, 2018, which is hereby incorporated by reference in its entirety.

### TECHNICAL FIELD

The present disclosure relates generally to the field of semiconductor technology, and more particularly, to stacked semiconductor devices and methods of manufacturing the same.

### BACKGROUND

In the field of semiconductor technology, there is a demand for stacking together a plurality of wafers having the same or different functions. After bonding a plurality of wafers to form a stacked semiconductor device, it is desirable to form an external connection via that at least partially penetrates the stacked semiconductor device to expose an external connection pad therein. In a subsequent step of packaging, the external connection pad may be connected to the external terminal by a lead or the like, and then the external connection via is filled with an insulating material. Before this, however, the external connection via is exposed to the environment for a long time, and is very vulnerable to corrosion of moisture or other substances in the environment.

Therefore, there is a need for new technologies.

### SUMMARY

One of aims of the present disclosure is to provide a new stacked semiconductor device and method of manufacturing the same.

According to a first aspect of the present disclosure, there is provided a stacked semiconductor device, comprising: a first substrate; a first insulating layer located on the first substrate; a second insulating layer located on the first insulating layer; a second substrate located on the second insulating layer; an external connection via extending through the second substrate in a first direction perpendicular to an upper surface of the second substrate and exposing an external connection pad, the external connection pad being located in the first insulating layer or the second insulating layer; and a protective ring formed in the second insulating layer and arranged to at least partially surround a sidewall of the external connection via with the first direction as an axial direction, but not to be exposed from the sidewall of the external connection via.

According to a second aspect of the present disclosure, there is provided a method for manufacturing a stacked semiconductor device, comprising: providing a first wafer, including: providing a first substrate, and forming a first insulating layer on the first substrate; providing a second wafer, including: providing a second substrate, and forming a second insulating layer on the second substrate and a protective ring located in the second insulating layer; inverting and placing the second wafer over the first wafer, and bonding the second insulating layer to the first insulating layer; and forming an external connection via that extends through the second substrate in a first direction perpendicular to an upper surface of the second substrate and exposes an external connection pad, the external connection pad being located in the first insulating layer or the second insulating layer, wherein the protective ring is formed so as to at least partially surround a sidewall of the external connection via with the first direction as an axial direction, but not to be exposed from the sidewall of the external connection via.

Further features of the present disclosure and advantages thereof will become apparent from the following detailed description of exemplary embodiments of the present disclosure with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according the following detailed description with reference of the accompanying drawings, wherein:

FIG. 1A shows a cross-sectional schematic view of a stacked semiconductor device according to one or more exemplary embodiments of the present disclosure;

FIG. 1B shows a schematic top view of a protective ring 150 as shown in FIG. 1A;

FIG. 2 shows a cross-sectional schematic view of a stacked semiconductor device according to one or more other exemplary embodiments of the present disclosure;

FIG. 3A shows a cross-sectional schematic view of a stacked semiconductor device according to one or more further exemplary embodiments of the present disclosure;

FIG. 3B shows a top perspective view of a protective ring 350 as shown in FIG. 3A;

FIG. 4 shows a flow chart of a method for manufacturing a stacked semiconductor device according to one or more exemplary embodiments of the present disclosure;

FIGS. 5A-5E show cross-sectional schematic views of the device at various steps of a method for manufacturing the stacked semiconductor device as shown in FIG. 1A, according to one or more exemplary embodiments of the present disclosure.

Note that, in the embodiments described below, in some cases the same portions or portions having similar functions are denoted by the same reference numerals in different drawings, and description of such portions is not repeated. In the present specification, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the present disclosure is not necessarily limited to the position, size, range, or the like as disclosed in the drawings and the like.

### DETAILED DESCRIPTION

In the existing stacked semiconductor device and the method of manufacturing the same, an external connection via will be possibly exposed to the external environment for a long time before packaging, which may cause corrosion of a functional structure formed around the external connection via (such as a wiring layer made of a metal material around the external connection via) in the stacked semiconductor device.

As a result of intensive studies, the inventor of the present application has proposed new stacked semiconductor devices and methods of manufacturing the same, which fully consider protection for the stacked semiconductor device, and which also fully consider simplification of the manufacturing method while avoiding corrosion due to exposure of the external connection via.

Various exemplary embodiments of the present disclosure will be described in details with reference to the accompanying drawings in the following. It should be noted that the relative arrangement of the components and steps, the numerical expressions, and numerical values set forth in these embodiments do not limit the scope of the present disclosure unless it is specifically stated otherwise.

The following description of at least one exemplary embodiment is merely illustrative in nature and is in no way intended to limit this disclosure, its application, or uses. That is to say, the structure and method discussed herein are illustrated by way of example to explain different embodiments according to the present disclosure. It should be understood by those skilled in the art that, these examples, while indicating the implementations of the present disclosure, are given by way of illustration only, but not in an exhaustive way. In addition, the drawings are not necessarily drawn to scale, and some features may be enlarged to show details of some specific components.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

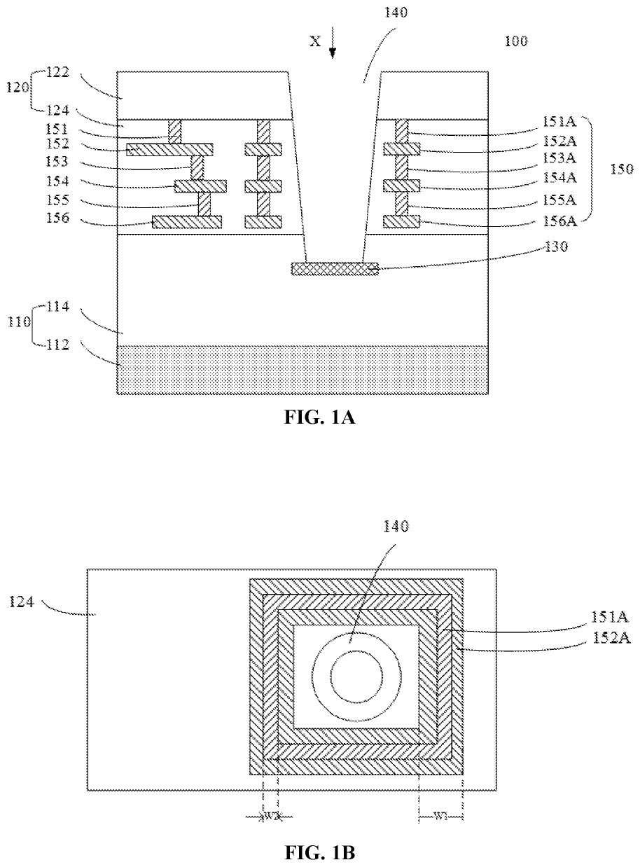

FIG. 1A shows a cross-sectional schematic view of a stacked semiconductor device 100 according to one or more exemplary embodiments of the present disclosure.

As shown in FIG. 1A, a stacked semiconductor device 100 may include: a first substrate 112, a first insulating layer 114 located on the first substrate 112, a second insulating layer 124 located on the first insulating layer 114, and a second substrate 122 located on the second insulating layer 124, wherein the first substrate 112 and the first insulating layer 114 may constitute a first wafer 110, the second substrate 122 and the second insulating layer 124 may constitute a second wafer 120, and the multi-layered stacked structure of the stacked semiconductor device 100 may be obtained by bonding the first wafer 110 and the second wafer 120.

Note that, in this document, the “first”, “second”, and the like are used only for distinguishing between various different components having the same name, and do not mean order, positional relationship, or the like. In addition, with respect to various different components having the same name, such as “first substrate” and “second substrate”, “first insulating layer” and “second insulating layer”, and the like, it is not meant that they all have the same structure(s) or component(s). For example, although not shown in the drawings, in most cases, the components formed in the “first substrate” and components formed in the “second substrate” are different, and the structures of the substrates may also be different. In some embodiments, the first substrate and the second substrate may be semiconductor substrates made of any semiconductor material suitable for semiconductor devices, such as Si, SiC, SiGe, and the like. In some other embodiments, the first substrate and the second substrate may be various composite substrates such as silicon on insulator (SOI), silicon germanium on insulator (SGOI), and the like. Those skilled in the art will appreciate that the substrate is not limited in any way and may be selected according to the actual application. Members of various device (not limited to a semiconductor device) may be formed in the first substrate and the second substrate (not shown in the drawings). In addition, the first insulating layer and the second insulating layer may have a single-layer or multi-layer structure, in which other layers or members, such as a wiring layer, a plug, a gate structure, and the like, may also be formed.

As shown in FIG. 1A, the stacked semiconductor device 100 may further include: an external connection via 140 which extends through the second substrate 122 in an X direction perpendicular to an upper surface of the second substrate 122 and exposes an external connection pad 130. Although the external connection pad 130 as shown in FIG. 1A is formed in the first insulating layer 114, the present disclosure is not limited thereto, and an external connection pad exposed by the external connection via may also be located in the second insulating layer, as described later with reference to other embodiments.

In some embodiments, the external connection pad 130 may be connected to other functional components in the stacked semiconductor device 100, for example, to plug(s), wiring layer(s), or other component(s) formed in the first insulating layer 114 when it is provided in the first insulating layer 114. Preferably, the external connection pad 130 may include aluminum. A compact aluminum oxide will be formed at a surface of the external connection pad comprising the aluminum material, so as to serve a function of protecting the external connection pad well. Further, the aluminum oxide on the surface of the external connection pad may be easily removed by a cleaning step before connecting the external connection pad by using a lead.

With continued reference to FIG. 1A, the stacked semiconductor device 100 may further include a protective ring 150 formed in the second insulating layer 124 and arranged to at least partially surround a sidewall of the external connection via 140 with the X direction as an axial direction, but not to be exposed from the sidewall of the external connection via. The protective ring 150 may include: protective layers 152A, 154A, and 156A formed in the second insulating layer, wherein each of the protective layers 152A, 154A, and 156A at least partially surrounds the external connection via 140 with the X direction as the axial direction; and protective layer connectors 151A, 153A, and 155A formed in the second insulating layer 124, wherein each of the protective layer connectors at least partially surrounds the external connection via 140 with the X direction as the axial direction, and wherein the protective layers 152A, 154A, and 156A and the protective layer connectors 151A, 153A, and 155A are alternately disposed in the X direction and connected to each other.

In FIG. 1A, a component in the protective ring 150 which is closest to the second substrate 122 is the protective layer connector 151A, and a component in the protective ring 150 which is closest to the first insulating layer 114 is the protective layer 156A. This is, however, not intended to be limiting. In some other embodiments according to the present disclosure, the component in the protective ring 150 which is closest to the second substrate 122 may be a protective layer or a protective layer connector, and the component in the protective ring 150 which is closest to the first insulating layer may be a protective layer or a protective layer connector.

Those skilled in the art will appreciate that, although FIG. 1 schematically shows that the protective ring 150 includes three protective layers 152A, 154A, and 156A and three protective layer connectors 151A, 153A, and 155A, the present disclosure is not so limited. In some embodiments according to the present disclosure, the protective ring may include any number of protective layers and any number of protective layer connectors. Note that since the protective rings and the protective ring connectors are alternately disposed, numbers of both of them are the same or only different by one.

In some embodiments according to the present disclosure, a protective ring extending in the X direction and at least partially surrounding the external connection via is formed by the alternate arrangement of the protective layers and the protective layer connectors. After the formation of the external connection via and before the packing, the protective ring serves a function of protecting the functional components (in particular the components close to the external connection via) in the second insulating layer, and prevents these components from corrosion due to external environment through the external connection via. Such a structure enables the stacked semiconductor device to have stronger environmental tolerance, thereby having better performance.

In some embodiments, the second insulating layer 124 may include at least one wiring layer formed therein and a plurality of plugs for connecting the at least one wiring layer, wherein each of the protective layers of the protective ring is a portion of a certain one of the wiring layers formed in the second insulating layer, and each of the protective layer connectors is a portion of the plurality of plugs formed in the second insulating layer. Taking FIG. 1A as an example, in the stacked semiconductor device 100, the second insulating layer 124 may further include wiring layers 152, 154, and 156 formed therein, plug(s) 151 formed over the wiring layer 152, plug(s) 153 formed between the wiring layers 152 and 154, and plug(s) 155 formed between the wiring layers 154 and 156, wherein the protective layer 152A is a portion of the wiring layer 152, the protective layer 154A is a portion of the wiring layer 154, and the protective layer 156A is a portion of the wiring layer 156, and wherein the protective layer connector 151A is one of the plug(s) 151, the protective layer connector 153A is one of the plug(s) 153, and the protective layer connector 155A is one of the plug(s) 155. Note that the wiring layers 152, 154, and 156 and the plugs 151, 153, and 155 shown in FIG. 1A are only used to schematically show the presence of the wiring layers and the plugs, and are not intended to limit the arrangement and connection relationships of the wiring layers and the plugs in the second insulating layer.

In some embodiments according to the present disclosure, the protective layer is a portion of the wiring layer, which means that the protective layer and the other portions of the wiring layer are in the same plane and may be formed by the same process step. Also, the protective layer connector is a portion of the plugs, which means that the protective layer connector may be formed as plug(s), that is, formed by the same process step as other plug(s) for connecting the wiring layer(s). By such an arrangement, the protective ring may be formed simultaneously in the process steps of forming the wiring layer(s) and the plug(s). Therefore, compared with a stacked semiconductor device without a protective ring, the method of manufacturing the stacked semiconductor device with the protective ring does not need to introduce any additional step, thereby taking into consideration simplification of the process while achieving better performance.

In some embodiments, the external connection pad is formed in the first insulating layer, and each wiring layer in the second insulating layer is formed over the first insulating layer, thus each wiring layer formed in the second insulating layer includes a protective layer. For example, as shown in FIG. 1A, the external connection pad 130 is formed in the first insulating layer 114, and thus each wiring layer in the second insulating layer 124 includes a protective layer.

In some other embodiments, the external connection pad is formed in the second insulating layer, and thus some or all of the wiring layers formed in the second insulating layer each include a protective layer. In a preferred embodiment, one or more of the wiring layers formed in the second insulating layer and located at positions not lower than the external connection pad each includes a protective layer.

In some embodiments according to the present disclosure, the sequentially alternating protective layers and protective layer connectors constitute a protective ring that at least partially surrounds the sidewall of the external connection via but is not exposed from the sidewall. If the protection effect is to be achieved as completely as possible, a tighter connection is needed between the protective layer and the protective layer connector, preferably without any gap between them. Based on this, in some embodiments, shapes of each of the protective layers and each of the protective layer connectors in a plane parallel to an upper surface of the second substrate are of a same type and of similar sizes. For example, the shapes of the protective layer connector and the protective layer in a plane parallel to the upper surface of the second substrate may both be rectangular rings, but sizes of both the rectangular rings may not be completely the same. Furthermore, a width of a side of ring of the protective layer may be greater than, less than or equal to that of the protective layer connector.

Further, in some embodiments, shape of each of the protective layers and each of the protective layer connectors in the plane parallel to the upper surface of the second substrate may be a closed ring. Preferably, the closed ring may be a rectangular ring or a regular hexagonal ring.

In some other embodiments, in view of that other functional structures may be formed in the second insulating layer, a part of the protective layer connectors and/or the protective layers may not be able to be formed as closed rings. In this case, shapes of each of the protective layers and each of the protective layer connectors in the plane parallel to the upper surface of the second substrate are rings, wherein, however, at least one side of the ring of at least one of the protective layers has an opening, and/or at least one side of the ring of at least one of the protective layer connectors has an opening. The opening of the ring of the protective layer and/or the protective layer connector may allow other functional components to pass through, thereby making more flexible the arrangement of the protective ring and other components. By such arrangement of the structure of the protection ring, the flexibility of design is ensured, and the relatively comprehensive isolation for the external connection via is realized as much as possible, so that the performance of the stacked semiconductor device is effectively improved.

As an example, FIG. 1B shows a top perspective view of the protective ring 150 of FIG. 1A. For simplicity of the view, FIG. 1B only schematically shows the top perspective shapes of the external connection via 140, the protective layer connector 151A, and the protective layer 152A. As shown in FIG. 1B, in the second insulating layer 124, both shapes of the protective layer 152A and the protective layer connector 151A in a plane parallel to the upper surface of the second substrate are closed rectangular rings. Preferably, a center of the rectangular ring of the protective layer 152A may be aligned with a center of the rectangular ring of the protective layer connector 151A. Further, a width W1 of a side of the rectangular ring of the protective layer 152A may be larger than a corresponding width W2 of the rectangular ring of the protective layer connector 151A. Those skilled in the art will appreciate that the structure as shown in FIG. 1B only serves as an example and is not intended to be limiting.

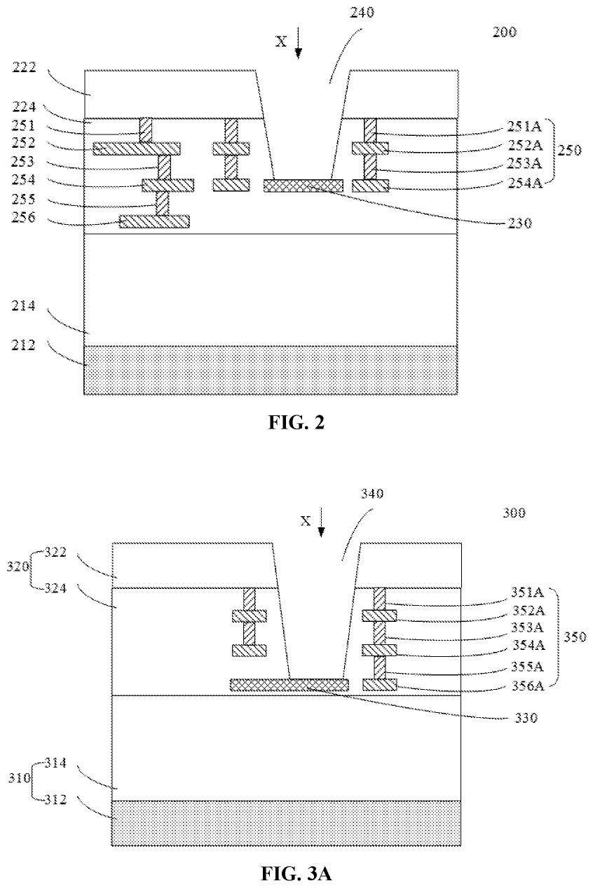

FIG. 2 illustrates a cross-sectional schematic view of a stacked semiconductor device 200 according to one or more other exemplary embodiments of the present disclosure. The stacked semiconductor device 200 as shown in FIG. 2 is a modified example of the stacked semiconductor device 100 as shown in FIG. 1A, so the foregoing description of the stacked semiconductor device 100 also applies here, and the following description focuses only on the differences of the stacked semiconductor device 200 with respect to the stacked semiconductor device 100.

The stacked semiconductor device 200 as shown in FIG. 2 differs from the stacked semiconductor device 100 as shown in FIG. 1 mainly in that the external connection pad 230 in FIG. 2 is formed in the second insulating layer 224. As shown in FIG. 2, the stacked semiconductor device 200 may include: a first substrate 212, a first insulating layer 214 located on the first substrate 212, a second insulating layer 224 located on the first insulating layer 214, and a second substrate 222 located on the second insulating layer 224. The stacked semiconductor device 200 may further include: an external connection via 240 which extends through the second substrate 222 in an X direction perpendicular to an upper surface of the second substrate 222 and exposes the external connection pad 230 located in the second insulating layer. Preferably, the external connection pad includes aluminum.

With continued reference to FIG. 2, the stacked semiconductor device 200 may further include a protective ring 250 formed in the second insulating layer 224 and arranged to at least partially surround a sidewall of the external connection via with the X direction as the axial direction, but not exposed from the sidewall of the external connection via. The protective ring 250 may include: a protective layer 252A formed in the second insulating layer, which at least partially surrounds the external connection via 240 with the X direction as the axial direction; and protective layer connectors 251A and 253A formed in the second insulating layer 224, each of the protective layer connectors at least partially surrounding the external connection via 240 with the X direction as the axial direction, wherein, the protective layer 252A and the protective layer connectors 251A and 253A are alternately arranged in the X direction and connected to each other.

With continued reference to FIG. 2, the second insulating layer 224 may further include wiring layers 252, 254, and 256 formed therein, plug(s) 251 formed over the wiring layer 252, plug(s) 253 formed between the wiring layers 252 and 254, and plug(s) 255 formed between the wiring layers 254 and 256, wherein, the protective layer 252A is a portion of the wiring layer 252, and wherein, the protective layer connector 251A is one of the plug(s) 251, and the protective layer connector 253A is one of the plug(s) 253. Note that the wiring layers 252, 254, and 256 and the plugs 251, 253, and 255 shown in FIG. 2 are only used to schematically show the presence of the wiring layer(s) and the plug(s), and are not intended to limit the arrangement and connection relationships of the wiring layer(s) and the plug(s) in the second insulating layer.

As shown in FIG. 2, in the stacked semiconductor device 200, the external connection pad 230 is formed in the second insulating layer 224, and the wiring layers located at positions not lower than the external connection pad 230 are the wiring layers 252 and 254, thus each of the wiring layers 252 and 254 includes a protective layer. The wiring layer 256 at a position lower than the external connection pad 230 does not include a protective layer.

For example, as shown in FIG. 2, the wiring layers 252 and 254 located at positions not lower than the external connection pad 230 in the second insulating layer include protective layers 252A and 254A, respectively.

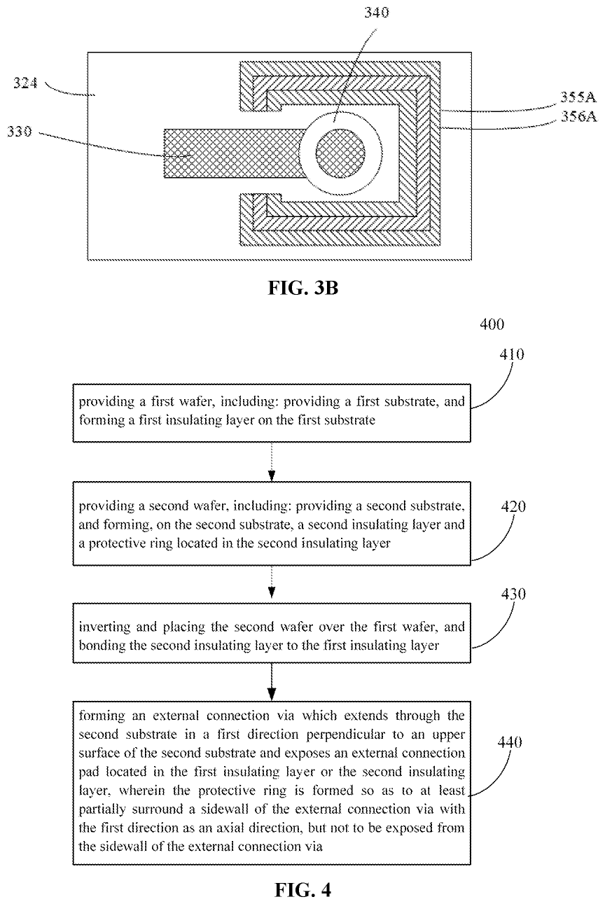

FIG. 3A shows a stacked semiconductor device 300 according to one or more further exemplary embodiments of the present disclosure. The stacked semiconductor device 300 as shown in FIG. 3A is a modified example of the stacked semiconductor device 100 as shown in FIG. 1A, so the foregoing description of the stacked semiconductor device 100 also applies here, and the following description focuses only on the differences of the stacked semiconductor device 300 with respect to the stacked semiconductor device 100.

As shown in FIG. 3A, the stacked semiconductor device 300 may include: a first substrate 312, a first insulating layer 314 located on the first substrate 312, a second insulating layer 324 located on the first insulating layer 314, and a second substrate 322 located on the second insulating layer 324. The stacked semiconductor device 300 may further include: an external connection via 340 which extends through the second substrate 322 in an X direction perpendicular to upper surface of the second substrate 322 and expose the external connection pad 330 in the second insulating layer. Preferably, the external connection pad 330 may include aluminum.

With continued reference to FIG. 3A, the stacked semiconductor device 300 may further include a protective ring 350 formed in the second insulating layer 324 and arranged to at least partially surround a sidewall of the external connection via 340 with the X direction as the axial direction, but not to be exposed from the sidewall of the external connection via. The protective ring 350 may include: protective layers 352A, 354A, and 356A formed in the second insulating layer, wherein each of the protective layers 352A, 354A, and 356A at least partially surrounds the external connection via 340 with the X direction as an axial direction; and protective layer connectors 351A, 353A, and 355A formed in the second insulating layer 324, wherein each of protective layer connectors at least partially surrounds the external connection via 340 with the X direction as the axial direction. The protective layers 352A, 354A, and 356A and the protective layer connectors 351A, 353A, and 355A are alternately arranged in the X direction and connected to each other.

As described above, in the stacked semiconductor device according to the present disclosure, the sequentially alternating protective layers and protective layer connectors constitute a protective ring at least partially surrounding the sidewall of the external connection via. For as comprehensive protection as possible, the protective layer and the protective layer connector may be connected more tightly, preferably without any gap between them. Based on this, in some embodiments, shapes of each of the protective layers and each of the protective layer connectors in a plane parallel to an upper surface of the second substrate are of a same type and of similar sizes. For example, the shapes of the protective layer connector and the protective layer in a plane parallel to the upper surface of the second substrate may both be rectangular rings, and both the rectangular rings have similar sizes.

In some other embodiments, in view of that other functional structures may be formed in the second insulating layer, a part of the protective layer connectors and/or the protective layers may not be able to be formed as closed rings. In this case, shapes of each of the protective layers and each of the protective layer connectors in the plane parallel to the upper surface of the second substrate are rings, wherein, however, at least one side of the ring of at least one of the protective layers has an opening and/or at least one side of the ring of at least one of the protective layer connectors has an opening. Such structure is illustrated by the device 300 in FIG. 3A.

FIG. 3B shows a top perspective view of the protective ring 350 shown in FIG. 3A. For simplicity of the view, FIG. 3B only schematically shows the top perspective shapes of the protective layer connector 355A and the protective layer 356A.

As shown in FIG. 3B, in the second insulating layer 324, since the external connection pad 330 extends in a plane parallel to a surface of the second insulating layer, one side of each of the rectangular rings of the protective layer 356A and the protective layer connector 355A is provided with an opening for the external connection pad 330 to pass through. The protection layers and the protection layer connectors located at positions higher than the external connection pad 330 are not affected and thus may be arranged as closed rectangular rings. Note that although FIG. 3B shows that the external connection pad 330 extends through the opening of the protective ring, the present disclosure is not limited thereto, and a wiring layer or other structures connected to the external connection pad may also extend through the opening of the protective ring.

In the protective ring shown in FIG. 3B, the opening in the ring of the protective layer and/or the protective layer connector may allow other functional components to pass through, thereby making more flexible the arrangement of the protective ring and other components. By such arrangement of the structure of the protection ring, not only can the highly compact layout design be realized, but also the isolation of the side wall of the external connection via can be realized as comprehensively as possible, so that the comprehensive performance of the stacked semiconductor device is effectively improved.

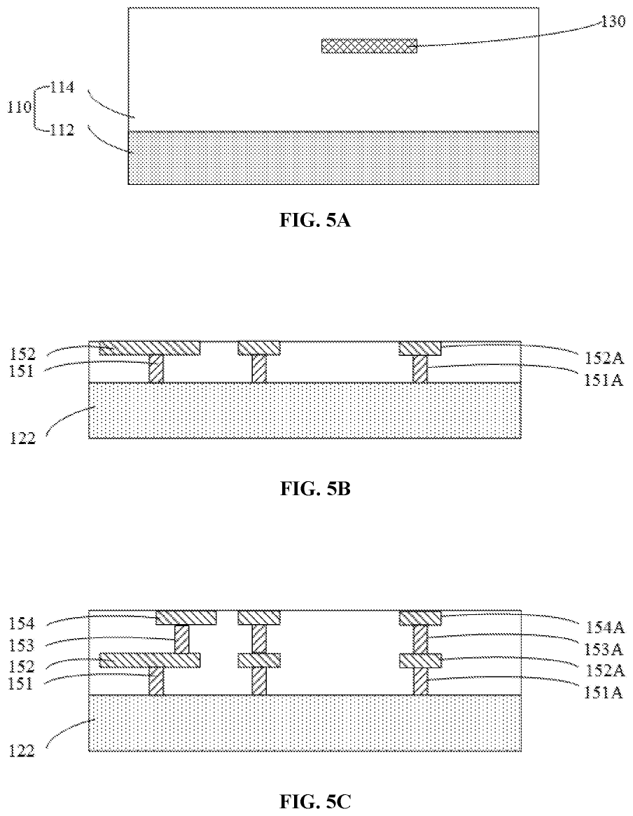

FIG. 4 shows a flow chart of a method 400 for manufacturing a stacked semiconductor device according to one or more exemplary embodiments of the present disclosure.

As shown in FIG. 4, at step 410, a first wafer is provided, comprising: providing a first substrate, and forming a first insulating layer on the first substrate.

At step 420, a second wafer is provided, comprising: providing a second substrate, and forming, on the second substrate, a second insulating layer and a protective ring located in the second insulating layer.

At step 430, the second wafer is inverted and placed over the first wafer, and the second insulating layer is bonded to the first insulating layer.

At step 440, an external connection via which extends through the second substrate in a first direction perpendicular to an upper surface of the second substrate and exposes an external connection pad located in the first insulating layer or the second insulating layer is formed, wherein the protective ring is formed so as to at least partially surround a sidewall of the external connection via with the first direction as an axial direction, but not to be exposed from the sidewall of the external connection via.

In some embodiments, forming the protective ring includes: alternately forming one or more protective layers and one or more protective layer connectors in the first direction in the second insulating layer, wherein each of the protective layers and each of the protective layer connectors at least partially surround the external connection via with the first direction as the axial direction, and the adjacent ones of the protective layers and the protective layer connectors are connected to each other.

In some embodiments, the second insulating layer includes at least one wiring layer formed therein and a plurality of plugs for connecting the at least one wiring layer. In a preferred embodiment, each of the protective layers may be a portion of a certain one of the wiring layers formed in the second insulating layer, and each of the protective layer connectors may be a portion of the plurality of plugs. The protective layer is a portion of the wiring layer, which means that the protective layer and the other portions of the wiring layer are in the same plane and may be formed by the same process step. Also, the connector is a portion of the plugs, which means that the protective layer connector may be formed as plug(s), that is, formed by the same process step as other plugs for connecting wiring layers. By such an arrangement, the protective ring may be formed simultaneously in the process steps of forming the wiring layer(s) and the plug(s). Therefore, compared with a stacked semiconductor device without a protective ring, the method of manufacturing the stacked semiconductor device with the protective ring does not need to introduce any additional step, thereby taking into consideration simplification of the process while achieving better performance.

In a specific embodiment, the forming, on the second substrate, a second insulating layer and a protective ring located in the second insulating layer may include: forming a first sub-layer of the second insulating layer, and forming a first wiring layer in the first sub-layer; forming a second sub-layer of the second insulating layer on the first sub-layer, and forming, in the second sub-layer, first plug(s) for connecting to the first wiring layer and a second wiring layer connected to the first plug, wherein, the first wiring layer includes a first protective layer, the second wiring layer includes a second protective layer, and the first plug(s) includes a first protective layer connector connecting the first protective layer and the second protective layer.

In some embodiments, the external connection pad is formed in the first insulating layer, and each of the wiring layers in the second insulating layer is formed over the first insulating layer, so that each of the wiring layers formed in the second insulating layer includes a protective layer. In some other embodiments, the external connection pad is formed in the second insulating layer, and some or all of the wiring layers formed in the second insulating layer each include a protective layer. In a preferred embodiment, one or more of the wiring layers formed at positions not lower than the external connection pad in the second insulating layer each include a protective layer.

In some embodiments, shapes of each of the protective layers and each of the protective layer connectors in a plane parallel to an upper surface of the second substrate are of a same type and of similar sizes. For example, the shapes of the protective layer connector and the protective layer in a plane parallel to the upper surface of the second substrate may be rectangular rings, but sizes of both the rectangular rings may not be completely the same. In some embodiments, shapes of each of the protective layers and each of the protective layer connectors in the plane parallel to the upper surface of the second substrate may be closed rings, e.g., rectangular rings or hexagonal rings. In some other embodiments, in view of that other functional structures may be formed in the second insulating layer, a part of the protective layer connectors and the protective layers may not be able to be formed as closed rings. In this case, shapes of each of the protective layers and each of the protective layer connectors in the plane parallel to the upper surface of the second substrate are rings, wherein, however, at least one side of the ring of at least one of the protective layers has an opening, and/or at least one side of the ring of at least one of the protective layer connectors has an opening.

For a more complete and comprehensive understanding of the present disclosure, a specific example of a method of manufacturing a stacked semiconductor device according to one or more exemplary embodiments of the present disclosure will be described in detail below, taking as an example the stacked semiconductor device 100 as shown in FIG. 1A. Note that this example is not intended to constitute a limitation of the present disclosure. For example, the present disclosure is not limited to the specific structure shown in FIG. 1A, but is applicable to all stacked semiconductor devices having the same requirements or design considerations. What has been described above in combination with FIGS. 1A, 1B and 4 may also be applied to the corresponding features.

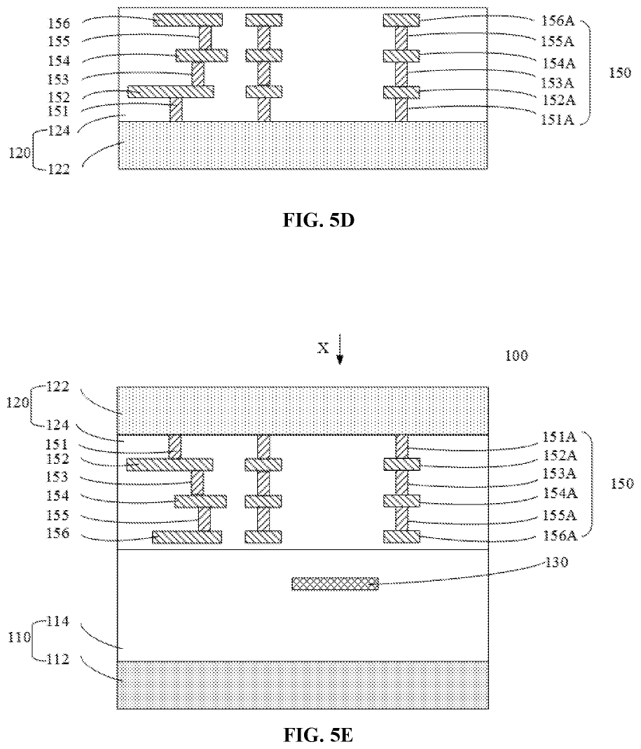

FIGS. 5A-5E show cross-sectional schematic views of the device at various steps of a method of manufacturing the stacked semiconductor device as shown in FIG. 1A, according to one or more exemplary embodiments of the present disclosure.

At FIG. 5A, a first wafer 110 is provided, comprising: providing a first substrate 112, forming a first insulating layer 114 on the first substrate 112, and forming an external connection pad 130 in the first insulating layer 114.

At FIG. 5B, a second substrate 122 is provided, a first sub-layer of a second insulating layer is formed on the second substrate 122, and plugs 151 and a wiring layer 152 are formed in the first sub-layer, wherein the plugs 151 include a protective layer connector 151A, and the wiring layer 152 includes a protective layer 152A.

At FIG. 5C, a second sub-layer of the second insulating layer is formed on the first sub-layer, and plugs 153 for connecting to the wiring layer 152 and a wiring layer 154 connected to the plugs 153 are formed in the second sub-layer, wherein, the wiring layer 154 includes a protective layer 154A, and the plugs 153 includes a protective layer connector 153A.

At FIG. 5D, a third sub-layer of the second insulating layer is formed on the second sub-layer, and plugs 155 for connecting to the wiring layer 154 and a wiring layer 156 connected to the plug 155 are formed in the third sub-layer, wherein, wiring layer 156 includes a protective layer 156A, and plugs 155 includes a protective layer connector 155A. To this end, through the steps of FIGS. 5B to 5D, a second wafer 120 including the second substrate 122 and the second insulating layer 124 is formed, wherein, the protective layers 152A, 154A, and 156A and the protective layer connectors 151A, 153A, and 155A constitute a protective ring 150.

Next, at FIG. 5E, the second wafer 120 is inverted and placed over the first wafer 110, and the second insulating layer 124 is bonded to the first insulating layer 114.

Finally, as shown in FIG. 1A, an external connection via 140 which extends through the second substrate 122 in an X direction perpendicular to an upper surface of the second substrate 122 and exposes the external connection pad 130 located in the first insulating layer 114 is formed. By setting a position of the external connection via 140 in advance, the protective ring 150 may be formed so as to at least partially surround a sidewall of the external connection via 140 with the X direction as an axial direction, but not to be exposed from the sidewall of the external connection via 140. Through the above steps, the stacked semiconductor device 100 as shown in FIG. 1A is finally obtained.

Those skilled in the art will appreciate that the present disclosure includes any other processes and structures necessary to form a semiconductor device in addition to the processes and structures illustrated.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

What is claimed is:

1. A stacked semiconductor device, comprising:
a first substrate;
a first insulating layer located on the first substrate;
a second insulating layer located on the first insulating layer;
a second substrate located on the second insulating layer;
an external connection via extending through the second substrate in a first direction perpendicular to an upper surface of the second substrate and exposing an external connection pad, the external connection pad being located in the first insulating layer or the second insulating layer; and
a protective ring formed in the second insulating layer and arranged to at least partially surround a sidewall of the external connection via with the first direction as an axial direction, but not to be exposed from the sidewall of the external connection via.

2. The stacked semiconductor device according to claim 1, wherein the protective ring includes:
one or more protective layers formed in the second insulating layer, each of the protective layers at least partially surrounding the external connection via with the first direction as an axial direction; and
one or more protective layer connectors formed in the second insulating layer, each of the protective layer connectors at least partially surrounding the external connection via with the first direction as an axial direction,
wherein the one or more protective layers and the one or more protective layer connectors are alternately arranged in the first direction and connected to each other.

3. The stacked semiconductor device according to claim 2, wherein the second insulating layer includes at least one wiring layer formed therein and a plurality of plugs for connecting the at least one wiring layer.

4. The stacked semiconductor device according to claim 3,
wherein each of the protective layers is a portion of a certain one of the wiring layers formed in the second insulating layer, and
wherein each of the protective layer connectors is a portion of the plurality of plugs.

5. The stacked semiconductor device according to claim 4, wherein,
when the external connection pad is formed in the first insulating layer, each of the wiring layers formed in the second insulating layer includes a protective layer; and
when the external connection pad is formed in the second insulating layer, some or all of the wiring layers formed in the second insulating layer each include a protective layer.

6. The stacked semiconductor device according to claim 5, wherein, when the external connection pad is formed in the second insulating layer, one or more of the wiring layers formed at positions not lower than the external connection pad in the second insulating layer each include a protective layer.

7. The stacked semiconductor device according to claim 2, wherein each of the protective layers and each of the protective layer connectors have shapes of a same type and of similar sizes in a planar view parallel to the upper surface of the second substrate.

8. The stacked semiconductor device according to claim 7, wherein shapes of each of the protective layers and each of the protective layer connectors are closed rings in the planar view parallel to the upper surface of the second substrate.

9. The stacked semiconductor device according to claim 8, wherein the closed rings are rectangular rings or hexagonal rings.

10. The stacked semiconductor device according to claim 7,
wherein shapes of each of the protective layers and each of the protective layer connectors are rings in the planar view parallel to the upper surface of the second substrate; and
wherein at least one side of the ring of at least one of the protective layers has an opening, and/or at least one side of the ring of at least one of the protective layer connectors has an opening.

11. A method for manufacturing a stacked semiconductor device, comprising:
providing a first wafer, including:
providing a first substrate, and
forming a first insulating layer on the first substrate;
providing a second wafer, including:
providing a second substrate, and
forming, on the second substrate, a second insulating layer and a protective ring located in the second insulating layer;
inverting and placing the second wafer over the first wafer, and bonding the second insulating layer to the first insulating layer; and
forming an external connection via that extends through the second substrate in a first direction perpendicular to an upper surface of the second substrate and exposes an external connection pad, the external connection pad being located in the first insulating layer or the second insulating layer,
wherein the protective ring is formed so as to at least partially surround a sidewall of the external connection via with the first direction as an axial direction, but not to be exposed from the sidewall of the external connection via.

12. The method according to claim 11, wherein forming the protective ring includes: forming one or more protective layers and one or more protective layer connectors which alternate with each other in the first direction in the second insulating layer, wherein each of the protective layers and each of the protective layer connectors at least partially surround the external connection via with the first direction as an axial direction, and adjacent ones of the protective layers and the protective layer connectors are connected to each other.

13. The method according to claim 12, wherein the second insulating layer includes at least one wiring layer formed therein and a plurality of plugs for connecting the at least one wiring layer.

14. The method according to claim 13,
wherein each of the protective layers is a portion of a certain one of the wiring layers formed in the second insulating layer, and
wherein each of the protective layer connectors is a portion of the plurality of plugs.

15. The method according to claim 14, wherein forming, on the second substrate, a second insulating layer and a protective ring located in the second insulating layer includes:
forming a first sub-layer of the second insulating layer, and forming a first wiring layer in the first sub-layer;
forming a second sub-layer of the second insulating layer on the first sub-layer, and forming first plugs for connecting to the first wiring layer and a second wiring layer connected to the first plugs in the second sub-layer,
wherein the first wiring layer includes a first protective layer, the second wiring layer includes a second protective layer, and the first plugs include a first protective layer connector for connecting the first protective layer and the second protective layer.

16. The method according to claim 14, wherein:
when the external connection pad is formed in the first insulating layer, each of the wiring layers formed in the second insulating layer includes a protective layer; and
when the external connection pad is formed in the second insulating layer, some or all of the wiring layers formed in the second insulating layer each include a protective layer.

17. The method according to claim 16, wherein when the external connection pad is formed in the second insulating layer, one or more of the wiring layers formed at positions not lower than the external connection pad in the second insulating layer each include a protective layer.

18. The method according to claim 12, wherein each of the protective layers and each of the protective layer connectors have shapes of a same type and of similar sizes in a planar view parallel to the upper surface of the second substrate.

19. The method according to claim 18, wherein shapes of each of the protective layers and each of the protective layer connectors are closed rings in the planar view parallel to the upper surface of the second substrate.

20. The method according to claim 18,
wherein shapes of each of the protective layers and each of the protective layer connectors are rings in the planar view parallel to the upper surface of the second substrate; and
wherein at least one side of the ring of at least one of the protective layers has an opening, and/or at least one side of the ring of at least one of the protective layer connectors has an opening.
